(19) United States
(12) Patent Application Publication
(10) Pub. No.: US 2024/0355751 A1
(43) Pub. Date: Oct. 24, 2024

(54) SELECTIVE UNDERCUT FOR GLASS CORE SUBSTRATE BRIDGE FIRST LEVEL INTERCONNECT (FLI) BUMP PLATING

(71) Applicant: Intel Corporation, Santa Clara, CA (US)

(72) Inventors: Sanjay THARMARAJAH, Queen Creek, AZ (US); Hiroki TANAKA, Gilbert, AZ (US); Clayton BRENNER, Chandler, AZ (US)

(21) Appl. No.: 18/136,722

(22) Filed: Apr. 19, 2023

(51) Int. Cl. H01L 23/538; H01L 21/48

(52) U.S. Cl. CPC H01L 23/5386; H01L 21/4846

(57) ABSTRACT

Embodiments disclosed herein include an electronic package. In an embodiment, the electronic package comprises a substrate and a pad on the substrate. In an embodiment, a layer is over the pad and the substrate, and an opening through the layer is above the pad. In an embodiment, sidewalls of the layer define the opening. In an embodiment, an undercut at an end of the opening adjacent to the pad is provided, where the undercut is positioned between the pad and the layer. In an embodiment, a bump is in the opening, where the bump at least partially fills the undercut

### TECHNICAL FIELD

Embodiments of the present disclosure relate to electronic systems, and more particularly to electronic packages with first level interconnect (FLI) bumps that include an anchoring undercut.

### BACKGROUND

The interconnects between a package substrate and an overlying die are generally made with a first level interconnect (FLI) architecture. In some instances, the FLI architecture comprises solder bumps. In advanced applications, the solder bumps are plated with an electrolytic plating process. As such, a seed layer over the solder resist is needed in order to plate up the solder bumps. This process works generally well for larger pitch solder bumps, but runs into problems in fine pitch areas. Fine pitch areas are typically located over embedded bridge architectures that provide communicative coupling between a pair of dies. Particularly, the fine pitch areas do not have any mechanical anchoring and are susceptible to bump delamination or other defects.

Further, bump plating solutions also tend to suffer from galvanic corrosion effects. For example, surface finishes that comprise gold are susceptible to corrosion during etching processes. As such, a protective layer is placed on the opposing side of the panel while processing through the etching process. Design rules are also in place to ensure that gold to copper ratios are minimized on the same side in order to prevent the galvanic corrosion.

### BRIEF DESCRIPTION OF THE DRAWINGS

FIG. 1 is a cross-sectional illustration of an interconnect without an anchoring undercut, in accordance with an embodiment.

FIG. 2A is a cross-sectional illustration of an interconnect with an anchoring undercut, in accordance with an embodiment.

FIG. 2B is a zoomed in cross-sectional illustration of the undercut, where the undercut stops before an edge of the pad, in accordance with an embodiment.

FIG. 2C is a zoomed in cross-sectional illustration of the undercut, where the undercut extends to an edge of the pad, in accordance with an embodiment.

FIG. 3A is a cross-sectional illustration of a two tiered structure, in accordance with an embodiment.

FIG. 3B is a cross-sectional illustration of the two tiered structure during a physical vapor deposition (PVD) line-of-sight deposition that results in shadowed surfaces that are not coated, in accordance with an embodiment.

FIG. 3C is a cross-sectional illustration of the two tiered structure during a chemical vapor deposition (CVD) process that covers an entire surface of the two tiered structure, in accordance with an embodiment.

FIG. 4A is a cross-sectional illustration of a package substrate that includes first pads and a second pad, in accordance with an embodiment.

FIG. 4B is a cross-sectional illustration of the package substrate after a resist is applied over the package substrate, in accordance with an embodiment.

FIG. 4C is a cross-sectional illustration of the package substrate after the resist is patterned to expose the first pads, in accordance with an embodiment.

FIG. 4D is a cross-sectional illustration of the package substrate after undercuts are provided between the first pads and the solder resist, in accordance with an embodiment.

FIG. 4E is a cross-sectional illustration of the package substrate after the resist is fully removed, in accordance with an embodiment.

FIG. 4F is a cross-sectional illustration of the package substrate after a conformal seed layer is applied with a CVD process, in accordance with an embodiment.

FIG. 4G is a cross-sectional illustration of the package substrate after a resist is applied over the solder resist to define the bumps, in accordance with an embodiment.

FIG. 4H is a cross-sectional illustration of the package substrate after the bumps are plated with an electrolytic plating process, in accordance with an embodiment.

FIG. 4I is a cross-sectional illustration of the package substrate after the resist is removed, in accordance with an embodiment.

FIG. 4J is a cross-sectional illustration of the package substrate after the exposed seed layer is removed, in accordance with an embodiment.

FIG. 5 is a plan view illustration of a package substrate that is covered by a resist that exposes the fine pitch regions that require an undercut, in accordance with an embodiment.

FIG. 6 is a cross-sectional illustration of an electronic system that includes a glass core package substrate with first interconnects over a bridge that comprise an undercut and second interconnects outside of the bridge, in accordance with an embodiment.

FIG. 7 is a schematic of a computing device built in accordance with an embodiment.

### EMBODIMENTS OF THE PRESENT DISCLOSURE

Described herein are electronic systems, and more particularly, electronic packages with first level interconnect (FLI) bumps that include an anchoring undercut, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, advanced packaging architectures require fine pitch interconnects in order to accommodate high density routing for embedded bridge architectures. In existing cases, for glass core architectures, the fine pitch interconnects do not include any mechanical anchoring. As such, the fine pitch interconnects are susceptible to damage. For example, solder bumps used for fine pitch applications can suffer from delamination or the like.

Further, it is to be appreciated that not all pads that are connected to the interconnects have the same structure. For example, large pads (e.g., for die side capacitors (DSCs), assembly fiducials, etc.) may include a surface finish, such as one that comprises gold. In such embodiments, etching of the fine pitch pads may result in the galvanic corrosion of the surface finish, which can cause damage to the package substrate. Accordingly, sacrificial layers may be needed on the opposite side of the panel, and/or strict gold to copper ratios may be needed. For example, a corrosion rate of galvanically coupled copper to gold is approximately twenty times higher when the area ratio of gold to copper is 25 compared to 0.5. Accordingly, flexibility in design of the package substrate is significantly limited.

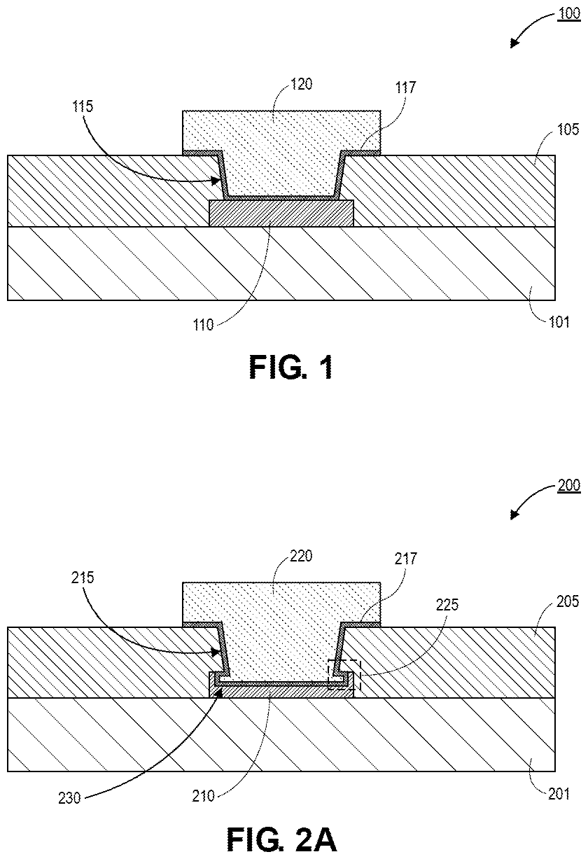

Referring now to FIG. 1, a cross-sectional illustration of a typical interconnect on electronic package 100 is shown, in accordance with an embodiment. As shown, a pad 110 may be provided over the package substrate 101. The package substrate 101 may comprise buildup layer (e.g., organic buildup film) and a core (not shown). The core may be glass in some embodiments. In an embodiment, a solder resist 105 may be applied over the top surface of the package substrate 101. A via opening 115 may be supplied through a portion of the solder resist 105 to expose the underlying pad 110. The via opening 115 may have tapered sidewalls in some instances. In order to allow for electrolytic plating of the bump 120, a seed layer 117 may be provided over the solder resist 105 and the pad 110.

As shown, the bump 120 substantially conforms to the shape of the via opening 115. Further, since there is no undercut between the top surface of the pad 110 and the solder resist 105, the bump 120 is not firmly secured in place. That is, the bump 120 may be susceptible to delamination, or other damage. Accordingly, the reliability of the electronic package 100 is negatively impacted.

Accordingly, embodiments disclosed herein include fine pitch interconnects that include an anchoring undercut. The anchor is provided by a portion of the bump extending between the top surface of the pad and the overlying solder resist. This can be done using a soft wet etching process. The cavity that is formed may then be lined with a seed layer. Particularly, the seed layer may be applied with a chemical vapor deposition (CVD) process. CVD processes are conformal and allow for the coating of shadowed surfaces (i.e., the surfaces of the cavity). An electrolytic plating process may then be implemented to plate up the bump, where the bump at least partially fills the remainder of the cavity not occupied by the seed layer.

The processing flow used in embodiments disclosed herein also leverage a masking process that simultaneously protects the surface finish of additional pads that do not require the undercut. For example, pads that include a surface finish comprising gold are not subject to galvanic corrosion. This eliminates the need for a sacrificial layer and relaxes the limits for the gold to copper ratio. As such, design flexibility is improved.

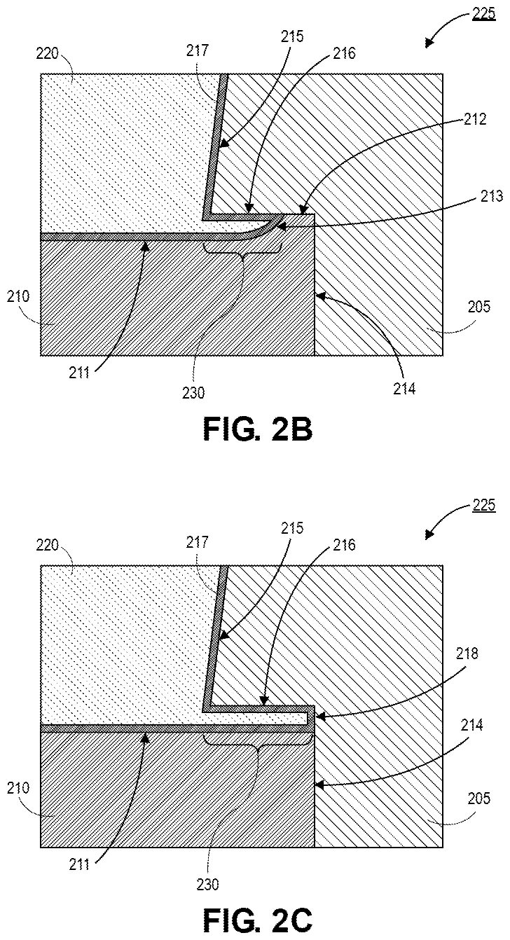

Referring now to FIG. 2A, a cross-sectional illustration of an electronic package 200 is shown, in accordance with an embodiment. In an embodiment, the electronic package 200 may comprise a package substrate 201. The package substrate 201 may comprise a core (not shown). Particularly, the core may comprise glass. That is, the core may include substantially all glass, as opposed to being an organic substrate with glass fiber reinforcement. Buildup layers (e.g., organic buildup film) may be laminated over and under the core. Conductive routing (not shown) may also be provided in the package substrate 201. For example, conductive routing may connect to the pad 210 that is shown over the package substrate 201.

In an embodiment, the pad 210 may be a copper pad 210 suitable for connecting to an overlying die (not shown). The pad 210 may be part of a fine pitch region of the electronic package 200. For example, the pad 210 may be provided over an embedded bridge (not shown) in order to enable high density interconnections over the package substrate 201. The pad 210 may have a diameter that is approximately 30um or smaller in some embodiments. Though, embodiments may also include larger pads 210. As used herein, “approximately” may refer to a range of values within ten percent of the stated value. For example, approximately 30 μm may refer to a range between 27 μm and 33 μm.

In an embodiment, a solder resist 205 is provided over the package substrate 201 and the pad 210. The solder resist 205 may include a via opening 215. The via opening 215 may have tapered sidewalls. That is, a width of the top of the via opening 215 may be wider than a width of the bottom of the via opening 215. In an embodiment, an undercut 230 may be provided at the bottom of the via opening 215. Particularly, the undercut 230 may be a location where a top surface of the pad 210 is spaced away from a surface of the solder resist 205.

In an embodiment, a seed layer 217 may line the via opening 215. Additionally, the seed layer 217 may line the undercut 230. As will be described in greater detail below, the seed layer 217 may be applied with a conformal deposition process (e.g., CVD) in order to coat the undercut 230 without having line-of-sight. The seed layer 217 may then be used in order to plate up a bump 220 in the undercut 230 and the via opening 215. The portion of the bump 220 that extends into the undercut 230 may provide mechanical anchoring for the bump 220, which improves reliability of the device.

Referring now to FIG. 2B, a zoomed in cross-sectional illustration of region 225 of the electronic package 200 is shown, in accordance with an embodiment. In an embodiment, the undercut 230 is shown as being defined by several surfaces. A top surface 211 of the pad 210 may form a bottom of the undercut 230, a sidewall surface 213 of the pad 210 may form the end of the undercut 230, and a surface 216 of the solder resist 205 may define a top of the undercut 230. As shown, the undercut 230 extends out past the sidewall of the via opening 215 towards the edge 214 of the pad 210. In some embodiments, the undercut 230 does not reach the edge 214 of the pad 210. For example, surface 212 may be provided between the end of the undercut 230 and the edge 214 of the pad 210. The undercut 230 may be lined by the seed layer 217 and at least partially filled by the bump 220.

In the illustrated embodiment, the surfaces defining the top and bottom of the undercut 230 are substantially flat, and the sidewall surface 213 is curved. While shown as being smooth surfaces, it is to be appreciated that the etching process used to form the undercut 230 may result in surfaces that are roughened, as is common with conductor etching operations. However, despite the roughened surfaces, it is to be appreciated that an edge of the undercut 230 will be set back from the edge of the via opening 215. In an embodiment, the length of the undercut 230 (i.e., the distance from the wall of the via opening 215 to the terminal edge of the undercut 230) may be up to approximately 10 μm, up to approximately 5 μm, or greater than approximately 1 μm. A thickness of the undercut 230 (i.e., a distance between the surface 216 of the solder resist 205 and the surface 211 or 213 of the pad 210) may be approximately 5 μm or less, or approximately 2 μm or less. In some embodiments, the length of the undercut 230 may be greater than a thickness of the undercut 230.

Referring now to FIG. 2C, a zoomed in cross-sectional illustration of region 225 is shown, in accordance with an additional embodiment. The region 225 in FIG. 2C may be substantially similar to the region 225 in FIG. 2B, with the exception of the structure of the undercut 230. Instead of stopping short of the edge 214 of the pad 210, the undercut 230 extends all the way to the edge 214 of the pad 210. That is, the top surface 211 of the pad 210 may be recessed across an entire width of the pad 210. Instead of the pad 210 serving as an edge of the undercut 230, the surface 218 of the solder resist 205 may define the edge of the undercut 230. The extension of the undercut 230 may be the result of a more aggressive etch. Additionally, while the surface 211 is shown as being substantially flat, the surface 211 may be roughened, curved, or have other topographies more characteristic of a conductor wet etching process. For example, an isotropic etch may not result in substantially rectangular undercut 230, as is shown in FIG. 2C. However, since the etching chemistry is tuned to selectively remove copper, the surface 216 and the surface 218 may have a roughness that is smoother than the roughness of the surface 211, since they will not be significantly etched.

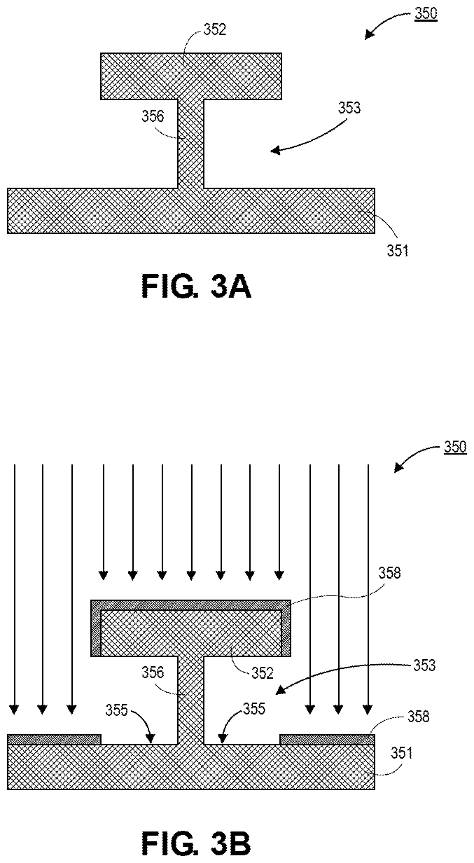

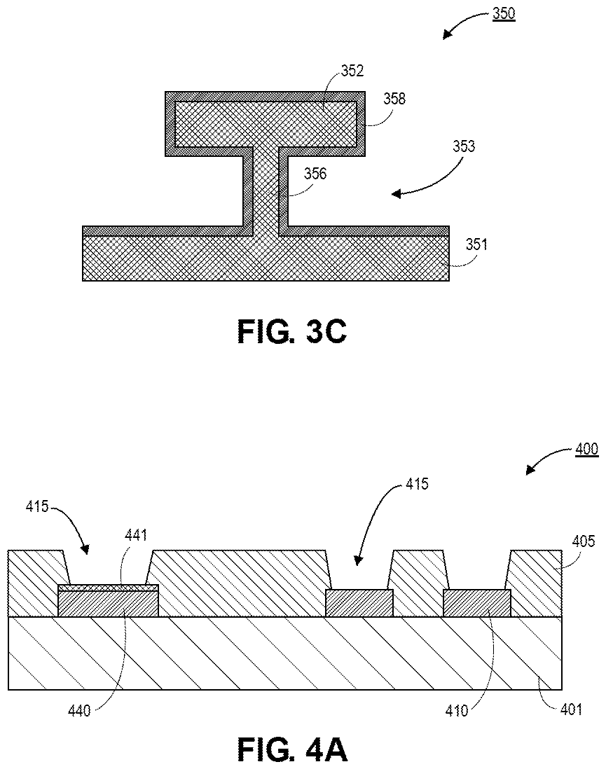

It is to be appreciated that the plating process used to form the seed layer in the undercut regions needs to be a conformal process, since there will be shadowing of surfaces within the undercut. An example of different types of plating processes are shown as an example in FIGS. 3A-3C. In FIG. 3A, a generic two tiered structure 350 is shown for illustrative purposes. Generally, the two tiered structure 350 includes a first layer 351 and a second layer 352 that are connected by a pillar 356. The first layer 351 may be wider than the second layer 352. The sidewalls of the pillar 356 are set back from the edge of the second layer 352 in order to form a cavity 353.

Referring now to FIG. 3B, a cross-sectional illustration of the two tiered structure 350 during a line of sight deposition process is shown, in accordance with an embodiment. For example, a line of sight deposition process may include a physical vapor deposition (PVD) process. As shown, the particles (indicated by the arrows) flow down towards the structure 350 in a substantially straight line. This results in deposition of the layer 358 on the top and sidewall surfaces of the second layer 352 and portions of the top surface of the first layer 351. However, shadowed regions 355 under the second layer 352 do not receive the layer 358. Similarly, the bottom surface of the second layer 352 and the sidewalls of the pillar 356 do not receive the coating of the layer 358. That is, the cavity 353 is not plated. If such an architecture was used for the undercuts described herein, a continuous seed layer may not be possible, and plating non-uniformity, voids (especially within the undercut), and other defects may occur.

Accordingly, embodiments disclosed herein include conformal deposition processes, such as the one described with respect to FIG. 3C. For example, the conformal deposition process may be a CVD process. An atomic layer deposition (ALD) process may also be used in some embodiments. As shown, the layer 358 is coated along all desired surfaces of the structure 350. That is, the entire top surface of the first layer is coated, the pillar sidewalls are coated, the bottom surface of the second layer is coated, and the top and sidewall surfaces of the second layer are coated. As such, the entire cavity 353 is coated, even though there is shadowing of surfaces. Such a conformal deposition process is the result of the deposition process being vapor or gas based, and the gas can flow into all surfaces. This is particularly beneficial when the cavity is narrow, as is the case of undercuts disclosed herein. Therefore, the high aspect ratio undercuts receive coating of the seed layer and can be plated up using an electrolytic plating process.

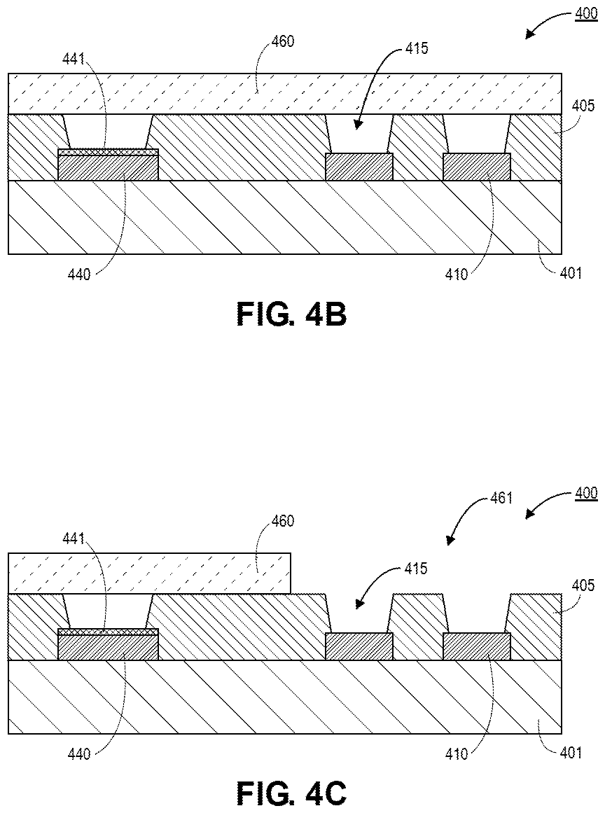

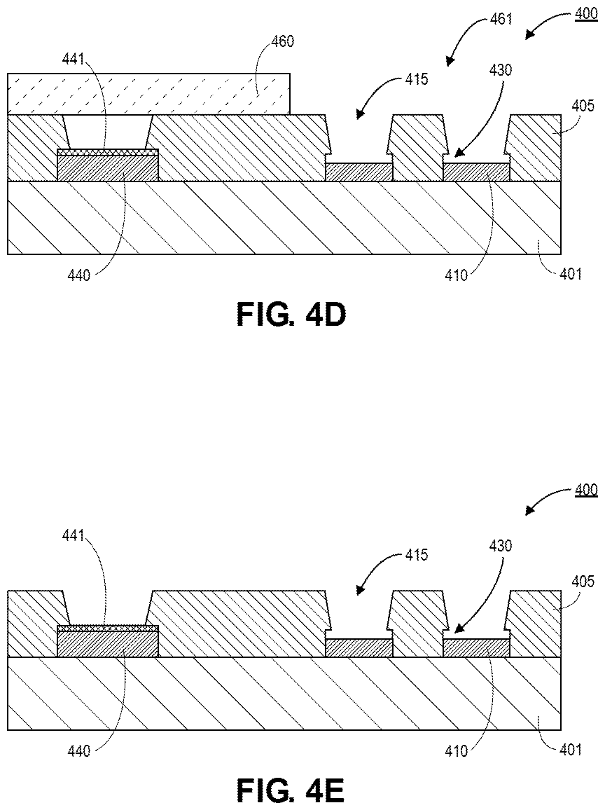

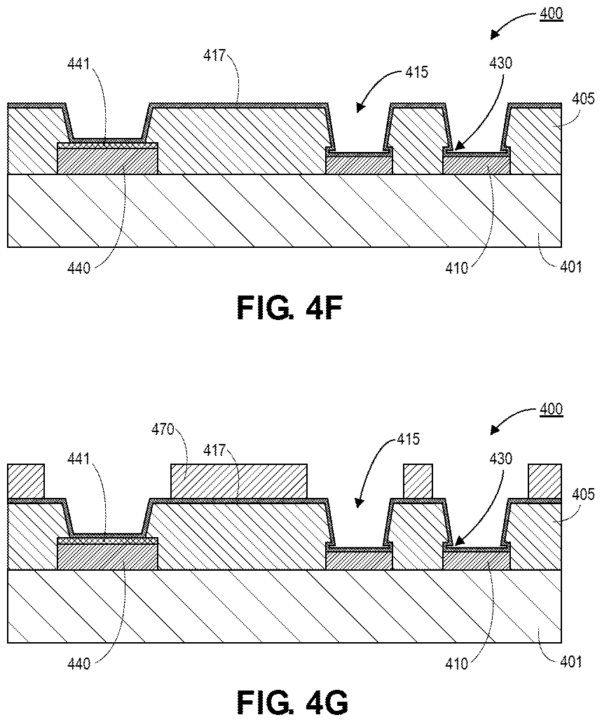

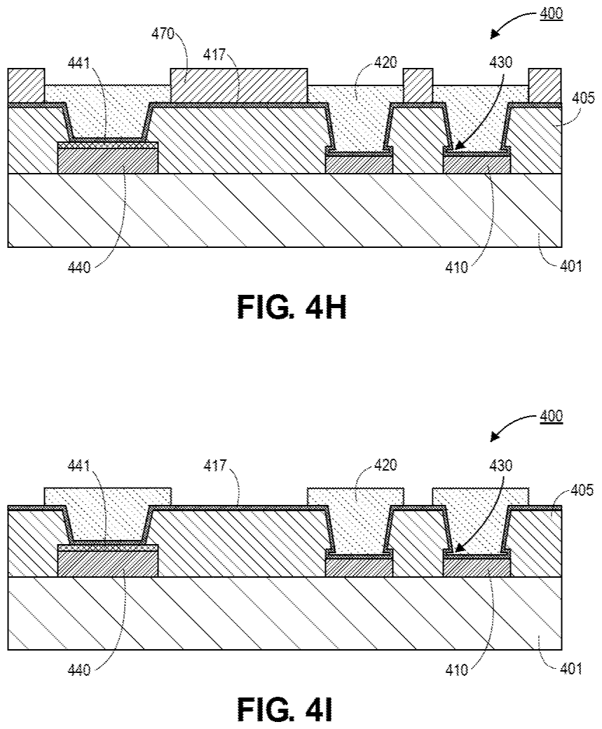

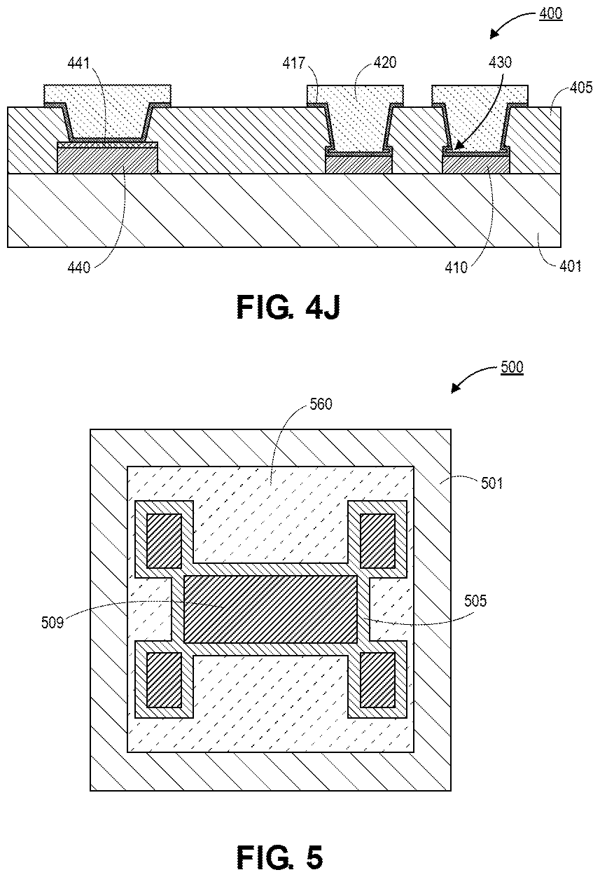

Referring now to FIGS. 4A-4J, a series of cross-sectional illustrations depicting a process for forming an electronic package 400 that includes fine pitch bumps that include an undercut for improved anchoring is shown, in accordance with an embodiment. Additionally, FIGS. 4A-4J illustrate how alternative pad types (e.g., comprising a gold surface finish) can be protected from galvanic corrosion during the etching process needed to form the undercuts.

Referring now to FIG. 4A, a cross-sectional illustration of an electronic package 400 at a stage of manufacture is shown, in accordance with an embodiment. In an embodiment, the electronic package 400 comprises a package substrate 401. For example, the package substrate 401 may include a glass core with organic buildup layers over and under the core. Conductive routing (not shown) may be electrically coupled to the first pads 410 and the second pad 440. In an embodiment, the first pads 410 are for fine pitch interconnects. For example, the first pads 410 may have diameters that are approximately 30um or smaller. Though, larger first pads 410 may also be used in some embodiments. The first pads 410 may be pads suitable for high density interconnects such as those used for coupling dies to an embedded bridge in the package substrate 401. The second pad 440 may be larger than the first pads 410. In some embodiments, the second pad 440 may also include a surface finish 441. For example, the surface finish may comprise gold. The second pad 440 may be used for DSCs, fiducials, power delivery, or any other purpose where larger pads are allowed.

In an embodiment, a solder resist 405 may be provided over the package substrate 401 and the pads 410 and 440. Via openings 415 may be provided through the solder resist 405 to expose the pads 410 and 440. The via openings 415 may have tapered sidewalls. For example, a top of the via opening 415 may be wider than a bottom of the via opening 415. Bottoms of the via openings 415 may be narrower than the underlying pad 410 or 440. After the via openings 415 are formed, a cleaning process may be executed.

Referring now to FIG. 4B, a cross-sectional illustration of the electronic package 400 after a resist layer 460 is applied over the solder resist 405 is shown, in accordance with an embodiment. In an embodiment, the resist layer 460 may bridge across the openings 415. Though, in other embodiments the resist layer 460 may fill or partially fill the openings 415. The resist layer 460 may be a dry film resist (DFR) or any other suitable photosensitive material that can be used as an etching mask. For example, conventional photoresist materials may be used in some embodiments.

Referring now to FIG. 4C, a cross-sectional illustration of the electronic package 400 after the resist layer 460 is patterned is shown, in accordance with an embodiment. In an embodiment, the resist layer 460 may be patterned with a photolithography process. That is, the resist layer 460 is exposed to electromagnetic radiation of a certain wavelength through a mask. The exposed resist layer 460 can then be developed in order to form openings 461. In an embodiment, the openings 461 are provided generally over the first pads 410. More generally, the openings 461 may be provided in locations where an undercut feature is desired. Since the solder resist 405 is resistant to the etching chemistry, the openings 461 does not need to be perfectly aligned with the openings 415, and a larger opening 461 may span two or more pads 410.

Referring now to FIG. 4D, a cross-sectional illustration of the electronic package 400 after an undercut etching process is implemented is shown, in accordance with an embodiment. In an embodiment, the undercut etching process may be a wet etching process that is selective to the material (e.g., copper) of the first pads 410. The etching process may be an isotropic etching process. The resulting undercuts 430 may extend out from the sidewall of the via opening 415 to the edge of the pad 410. In an embodiment, the undercuts 430 may have a length that is greater than their thickness. The length of the undercuts 430 may be approximately 10 μm or less, or approximately 5 μm or less. The thickness may be up to approximately 5 μm in some embodiments. The undercuts 430 shown in FIG. 4D are just one example of a suitable undercut 430 architecture. It is to be appreciated that undercuts 430 may take any shape or topography, such as those described in greater detail herein.

It is to be appreciated that the second pad 440 is protected during the etching process. That is, the resist 460 remains over the opening 415 over the second pad 440 during the etching process. This protects the surface finish 441 from experiencing galvanic corrosion. Accordingly, different types of pads can be processed without design rules limiting gold to copper ratios, or without sacrificial plates.

Referring now to FIG. 4E, a cross-sectional illustration of the electronic package 400 after the resist layer 460 is completely removed is shown, in accordance with an embodiment. The resist layer 460 may be removed with a resist stripping process, or the like. Removal of the resist layer 460 results in the exposure of the surface finish 441 over the second pad 440.

Referring now to FIG. 4F, a cross-sectional illustration of the electronic package 400 after a seed layer 417 is applied is shown, in accordance with an embodiment. In an embodiment, the seed layer 417 may be applied with a conformal deposition process. For example, a CVD or ALD process may be used in order to form the seed layer 417. The seed layer 417 may conform to the topography of the via openings 415, including the undercuts 430. That is, the deposition process does not suffer from shadowing effects like a line of sight deposition process (e.g., PVD) would experience. The seed layer 417 may comprise copper or the like. In an embodiment, the seed layer 417 may have a thickness that is 100 nm or less. The small thickness of the seed layer 417 allows for the undercut 430 to be lined, without entirely filling the undercut 430.

Referring now to FIG. 4G, a cross-sectional illustration of the electronic package 400 after a bump patterning layer 470 is applied over the seed layer 417 is shown, in accordance with an embodiment. The bump patterning layer 470 may be a resist (e.g., a photoresist, a DFR, or the like). The bump patterning layer 470 may have openings that are aligned with the via openings 415. The bump patterning layer 470 blocks the seed layer 417 from the plating solution and prevents plating. As such, the via openings 415 and the undercuts 430 will be plated up with the bumping material (e.g., solder).

Referring now to FIG. 4H, a cross-sectional illustration of the electronic package 400 after the bumps 420 are plated is shown, in accordance with an embodiment. In an embodiment, the bumps 420 may be plated with an electrolytic plating process. The bumps 420 may comprise solder or any other suitable FLI bumping material. As shown, the bumps 420 may at least partially fill the undercuts 430. This provides an anchoring effect that minimizes bump 420 delamination.

Referring now to FIG. 4I, a cross-sectional illustration of the electronic package 400 after the bump patterning layer 470 is removed is shown, in accordance with an embodiment. The bump patterning layer 470 may be removed with a resist stripping process or the like. Removal of the bump patterning layer 470 re-exposes the underlying seed layer 417.

Referring now to FIG. 4J, a cross-sectional illustration of the electronic package 400 after residual portions of the seed layer 417 are removed is shown, in accordance with an embodiment. The seed layer 417 may be removed with a timed etching process, such as a flash etch or the like. Removal of the seed layer 417 results in the bumps 420 being electrically isolated from each other.

Referring now to FIG. 5, a plan view illustration of an electronic package 500 is shown, in accordance with an embodiment. FIG. 5 is a map that illustrates where the openings in the resist layer 560 are located. As shown, a substrate 501 is provided. The substrate 501 illustrated in FIG. 5 may be the glass core around a periphery of the buildup layers. A solder resist 505 may be provided over the substrate 501. Openings through the solder resist 505 may expose fine pitch regions 509. While shown as a generic block, the fine pitch regions 509 may include two or more fine pitch pads similar to the structure shown in FIGS. 4A-4J. The resist layer 560 may cover the substrate 501 in areas not occupied by the fine pitch regions 509. The fine pitch regions 509 can then be processed to form undercuts in order to enable bump anchoring.

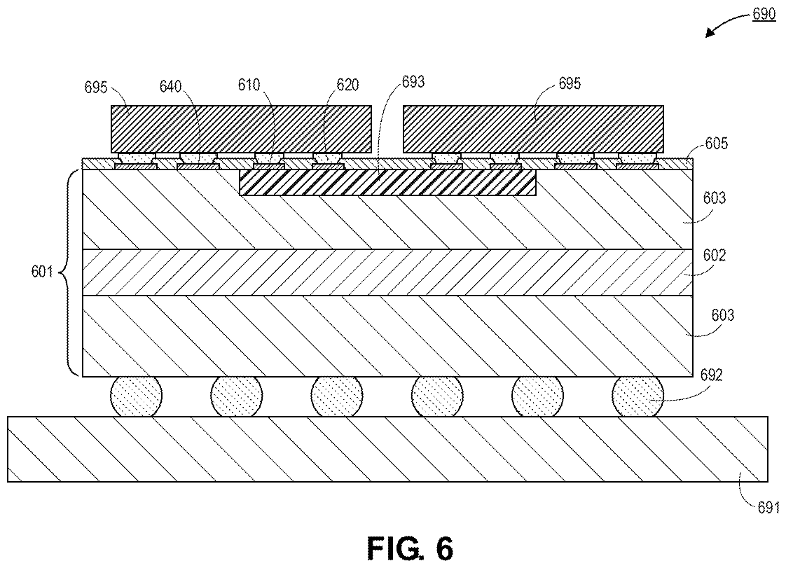

Referring now to FIG. 6, a cross-sectional illustration of an electronic system 690 is shown, in accordance with an embodiment. The electronic system 690 may comprise a board 691, such as a printed circuit board (PCB). Interconnects 692 may couple the board 691 to a package substrate 601. The package substrate 601 may comprise a core 602, such as a glass core 602, and buildup layers 603 over and under the core 602.

In an embodiment, an embedded bridge 693 may be incorporated into the buildup layers 603. The bridge 693 may provide high density routing that electrically couples together a pair of dies 695. Interconnects 620 over pads 610 may be used in order to make the connection between the dies 695 and the bridge 693. For example, the interconnects 620 over the pads 610 may be anchored with an undercut architecture similar to any of the undercut architectures described in greater detail herein. In an embodiment, other pads 640 may be coupled to the dies 695 outside of the bridge 693. For example, the other pads 640 may include a surface finish, such as one comprising gold. The bumps 620 may be surrounded, at least partially, by a solder resist layer 605.

In an embodiment, the dies 695 may include any suitable die. For example, the dies 695 may include a central processing unit (CPU), a graphics processing unit (GPU), an XPU, a system on a chip (SoC), a communications die, a memory die, or the like.

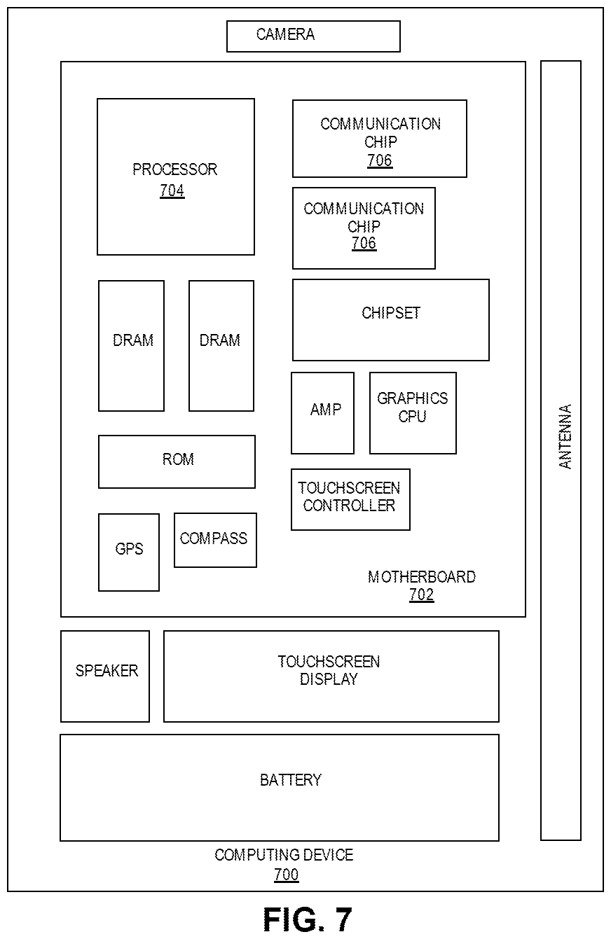

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package with a package substrate with a glass core and bumps that are anchored by an undercut feature, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of an electronic package with a glass core and bumps that are anchored by an undercut feature, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a substrate; a pad on the substrate; a layer over the pad and the substrate; an opening through the layer above the pad, wherein sidewalls of the layer define the opening; an undercut at an end of the opening adjacent to the pad, wherein the undercut is positioned between the pad and the layer; and a bump in the opening, wherein the bump at least partially fills the undercut.

Example 2: the electronic package of Example 1, wherein the opening and the undercut is lined by a seed layer.

Example 3: the electronic package of Example 1 or Example 2, wherein the undercut extends under the layer a distance up to approximately 10 μm.

Example 4: the electronic package of Examples 1-3, wherein an edge of the undercut stops before the edge of the bump.

Example 5: the electronic package of Examples 1-4, wherein the undercut has non-planar surfaces.

Example 6: the electronic package of Examples 1-5, wherein the bump is a solder bump.

Example 7: the electronic package of Examples 1-6, wherein the substrate comprises a package substrate with a core.

Example 8: the electronic package of Example 7, wherein the core is a glass core.

Example 9: the electronic package of Examples 1-8, further comprising: a second bump under the layer; and a second opening through the layer above the second bump, wherein the second opening meets the second bump without an undercut.

Example 10: the electronic package of Example 9, wherein the second bump comprises a surface finish that comprises gold.

Example 11: an electronic package, comprising: a package substrate with a glass core; a first pad on the package substrate; a second pad on the package substrate; a layer over the first pad and the second pad; a first opening through the layer over the first pad, wherein the first opening comprises an undercut between the first pad and the layer;

and a second opening through the layer over the second pad, wherein the second opening is without an undercut between the second pad and the layer.

Example 12: the electronic package of Example 11, wherein a length of the undercut is up to approximately 10 μm.

Example 13: the electronic package of Example 11 or Example 12, wherein the second pad comprises a surface finish that comprises gold.

Example 14: the electronic package of Examples 11-13, wherein the first opening, the undercut, and the second opening are lined by a seed layer.

Example 15: the electronic package of Example 14, wherein the seed layer has a thickness up to approximately 100 nm.

Example 16: the electronic package of Examples 11-15, wherein a solder bump fills the first opening and the second opening.

Example 17: the electronic package of Examples 11-16, wherein a diameter of the first pad is smaller than a diameter of the second pad.

Example 18: an electronic system, comprising: a board; a package substrate coupled to the board, wherein the package substrate comprises: a glass core; and an embedded bridge; a first die coupled to the package substrate by at least a first interconnect over the embedded bridge, wherein the first interconnect comprises a first undercut; and a second die coupled to the package substrate by at least a second interconnect over the embedded bridge, wherein the second interconnect comprises a second undercut.

Example 19: the electronic system of Example 18, wherein the first die is communicatively coupled to the second die by the embedded bridge.

Example 20: the electronic system of Example 18 or Example 19, wherein the electronic system is part of a personal computer, a server, a mobile device, a tablet, or an automobile.

What is claimed is:

1. An electronic package, comprising:
a substrate;
a pad on the substrate;
a layer over the pad and the substrate;
an opening through the layer above the pad, wherein sidewalls of the layer define the opening;
an undercut at an end of the opening adjacent to the pad, wherein the undercut is positioned between the pad and the layer; and
a bump in the opening, wherein the bump at least partially fills the undercut.

2. The electronic package of claim 1, wherein the opening and the undercut is lined by a seed layer.

3. The electronic package of claim 1, wherein the undercut extends under the layer a distance up to approximately 10 μm.

4. The electronic package of claim 1, wherein an edge of the undercut stops before the edge of the bump.

5. The electronic package of claim 1, wherein the undercut has non-planar surfaces.

6. The electronic package of claim 1, wherein the bump is a solder bump.

7. The electronic package of claim 1, wherein the substrate comprises a package substrate with a core.

8. The electronic package of claim 7, wherein the core is a glass core.

9. The electronic package of claim 1, further comprising:
a second bump under the layer; and
a second opening through the layer above the second bump, wherein the second opening meets the second bump without an undercut.

10. The electronic package of claim 9, wherein the second bump comprises a surface finish that comprises gold.

11. An electronic package, comprising:
a package substrate with a glass core;
a first pad on the package substrate;
a second pad on the package substrate;
a layer over the first pad and the second pad;
a first opening through the layer over the first pad, wherein the first opening comprises an undercut between the first pad and the layer; and
a second opening through the layer over the second pad, wherein the second opening is without an undercut between the second pad and the layer.

12. The electronic package of claim 11, wherein a length of the undercut is up to approximately 10 μm.

13. The electronic package of claim 11, wherein the second pad comprises a surface finish that comprises gold.

14. The electronic package of claim 11, wherein the first opening, the undercut, and the second opening are lined by a seed layer.

15. The electronic package of claim 14, wherein the seed layer has a thickness up to approximately 100 nm.

16. The electronic package of claim 11, wherein a solder bump fills the first opening and the second opening.

17. The electronic package of claim 11, wherein a diameter of the first pad is smaller than a diameter of the second pad.

18. An electronic system, comprising:
a board;
a package substrate coupled to the board, wherein the package substrate comprises:
a glass core; and
an embedded bridge;
a first die coupled to the package substrate by at least a first interconnect over the embedded bridge, wherein the first interconnect comprises a first undercut; and
a second die coupled to the package substrate by at least a second interconnect over the embedded bridge, wherein the second interconnect comprises a second undercut.

19. The electronic system of claim 18, wherein the first die is communicatively coupled to the second die by the embedded bridge.

20. The electronic system of claim 18, wherein the electronic system is part of a personal computer, a server, a mobile device, a tablet, or an automobile.
